(19) United States
(12) Patent Application Publication
(10) Pub. No.: US 2009/0203166 A1
(43) Pub. Date: Aug. 13, 2009

(54) Zinc Oxide Materials and Methods for Their Preparation

(76) Inventors: John Vedamuthu Kennedy, Lower Hutt (NZ); Andreas Markwitz, Lower Hutt (NZ)

Correspondence Address: DANN, DORFMAN, HERRELL & SKILLMAN, 1601 MARKET STREET, SUITE 2400, PHILADELPHIA, PA, 19103-2307, US

(21) Appl. No.: 12/296,326

(22) PCT Filed: Apr. 5, 2007
(86) PCT No.: PCT/NZ2007/000073

§ 371 Date: Mar. 18, 2009

(30) Foreign Application Priority Data
Apr. 7, 2006 (NZ) 542917

(51) Int. Cl. H01L 21/425

(52) U.S. Cl. 438/104; 257/E21.473

(57) ABSTRACT

A method for preparing p-type zinc oxide (ZnO) is described. The p-type ZnO is prepared by implanting low energy acceptor ions into an n-type ZnO substrate and annealing. In an alternative embodiment, the n-type ZnO substrate is pre-doped by implanting low energy donor ions. The p-type ZnO may have application in various optoelectronic devices, and a p-n junction formed from the p-type ZnO prepared as described above and a bulk n-type ZnO substrate is also described.

### TECHNICAL FIELD

The present invention relates to zinc oxide semiconductor materials. More particularly, but not exclusively, it relates to the preparation of p-type zinc oxide.

### BACKGROUND ART

Development of p-type conductivity zinc oxide (ZnO) materials has been identified as an emerging research and development initiative for next generation short-wavelength optoelectronic devices. When compared with materials that have been the subject of most research, such as gallium nitride (GaN), p-type ZnO has very promising electrical and optical properties that could prove superior in the development of optoelectronic devices.

The main advantages of ZnO as a light emitter are its large exciton binding energy (60 meV), which provides optically efficient excitonic behaviour, and its wide band-gap. Both of these advantages are extremely valuable in optoelectronic applications. ZnO layers show n-type conductivity. However, the key challenges in developing ZnO technology for optoelectronic applications are the need for p-type conductivity, establishing what kind of doping process results in p-type material, and the subsequent fabrication of a p-n junction. Obtaining p-type ZnO is critical for extending the optoelectronic applications of ZnO and has so far proven difficult.

The growth of n-type ZnO is relatively simple, because shallow donor impurities—such as Al, Ga and In—are readily incorporated into the ZnO lattice. Numerous fabrication techniques have been successfully implemented in the growth of such n-type materials, including: metal-organic chemical vapour deposition (MOCVD); molecular beam expitaxy (MBE); sol-gel deposition; DC and/or RF magnetron sputtering; reactive evaporation; spray pyrolysis; and pulsed laser deposition (Wenas et al. 1994; Dutta and Basu 1993; and Guo, Tabata and Kawai 2001).

Recent theoretical studies have suggested that zinc vacancies in the ZnO matrix act as possible deep acceptors. Of the group V elements phosphorus, arsenic and nitrogen, nitrogen atoms substituting for oxygen in the ZnO film have shown the most promise of being a reasonably shallow acceptor in ZnO (Look 2001; Minegishi et al. 1997; and Yan et al. 2001).

A co-doping donor-acceptor method has also been proposed for producing p-type ZnO material (Yamamoto et al. 1999; and Joseph, Tabata and Kawai 1999). The use of electron paramagnetic resonance (EPR) and photoluminescence (PL) techniques to study the character of acceptors in ZnO materials and doping properties related to fundamental growth parameters has been described. It was found that nitrogen is the best available acceptor for ZnO (Kaschner et al. 2002; and Garces et al. 2003).

P-type doping of ZnO has been realised during the film growth by chemical vapour deposition, molecular beam epitaxy, pulsed laser deposition and other conventional techniques (Ryu et al. 2000; Bagnall et al. 1997; and Vaithianathan et al. 2005). However, to date there remains a need for a reproducible method for preparing p-type ZnO material.

The doping of various optoelectronic materials, such as GaN, by ion implantation has been investigated (Pearton et al. 1995; and Zolper et al. 1996). The doping of ZnO by ion implantation has also been investigated. However, both of the reported studies were unsuccessful at producing p-type ZnO. Thomas and Walsh (1973) describe 200-350 keV implantations of P, V, N, O, Ar and Ne into Li-doped ZnO crystals. Miyakawa, Ueda and Hosono (2002) describe a 60 keV nitrogen implantation into ZnO thin films.

It is an object of the present invention to provide a method for preparing p-type ZnO, and the product of this method, which overcomes or at least ameliorates some of the abovementioned disadvantages, and/or which at least provides the public with a useful choice.

Other objects of the invention may become apparent from the following description which is given by way of example only.

### DISCLOSURE OF INVENTION

In a first aspect, the present invention provides a method of preparing p-type zinc oxide (ZnO) comprising the steps of:
providing an n-type ZnO substrate;
doping the substrate by implanting low energy acceptor ions into the substrate; and
in a chamber at less than atmospheric pressure, heating the implanted substrate with an electron beam to a peak temperature, holding the peak temperature for a predetermined time and decreasing the substrate temperature.

Preferably, the acceptor ions are selected from nitrogen, arsenic, and phosphorus ions. More preferably, the acceptor ions are nitrogen ions.

Preferably, the method of the invention results in p-type ZnO to a depth of between about 1 nm and about 100 nm.

Preferably, the step of implanting low energy acceptor ions uses a mass-separated focussed beam of low energy acceptor ions.

Preferably, the acceptor ions are implanted with a beam energy below about 70 keV. In certain embodiments, the acceptor ions are implanted with a beam energy between about 5 keV and about 70 keV. Alternatively, the acceptor ions may be implanted with a beam energy between about 5 keV and about 50 keV. In other preferred embodiments, the acceptor ions are implanted with a beam energy, below about 50 keV, below about 45 keV, below about 40 keV, below about 35 keV, below about 30 keV, or below about 25 keV.

Preferably, the ion fluence during the implanting is between about 1×10¹⁵ ions cm⁻² and about 5×10¹⁶ ions cm⁻².

In one embodiment, the n-type ZnO substrate is bulk ZnO, such as single crystal ZnO. In an alternative embodiment, the n-type ZnO substrate is a layer of n-type ZnO on a second material. Suitable materials are known to those persons skilled in the art. Preferred materials include semi-conductors and insulators including, but not limited to: silicon; SiO₂; and glass.

In those embodiments wherein the acceptor ion is nitrogen, the acceptor ions are preferably implanted with a beam energy below about 70 keV, more preferably below about 50 keV. In other preferred embodiments, wherein the acceptor ion is nitrogen, the acceptor ions are implanted with a beam energy below about 45 keV, below about 40 keV, below about 35 keV, below about 30 keV, or below about 25 keV. In certain embodiments, wherein the acceptor ion is nitrogen, the acceptor ions are implanted with a beam energy above about 5 keV.

Preferably, the resultant atomic % of acceptor in the substrate is below about 10 atomic %. More preferably, the atomic % of acceptor in the substrate is between about 0.1 atomic % and about 5.0 atomic %.

Preferably, the heating is carried out under vacuum conditions with residual gas pressure of below about 10⁻⁶ mbar. Preferably, the residual gas pressure is lowered using one or more oil-free vacuum pumps and a cold trap.

Preferably, the electron beam is raster scanned over the substrate surface in the heating step. The electron beam is typically raster scanned over the substrate with a frequency between about 1 and about 10 kHz. The frequency of raster scanning is selected to provide homogeneity of the temperature across the substrate surface.

Preferably, the energy of the electron beam is about 20 keV.

Preferably, the substrate is heated with a temperature gradient of between about 5° C./s and about 10° C./s.

Preferably, the peak temperature is below about 1,200° C. More preferably, the peak temperature is between about 500° C. and about 1,000° C.

Preferably, the substrate is held at the peak temperature for between about 5 seconds and about 2 hours.

Preferably the temperature of the substrate is decreased with a temperature gradient of between about 5° C./s and about 10° C./s.

In one preferred embodiment of the invention, the method further comprises, prior to the step of implanting low energy acceptor ions into the substrate, the additional step(s) of:
pre-doping the substrate by implanting donor ions into the substrate; and, optionally;
in a chamber at less than atmospheric pressure, thermally annealing the implanted substrate.

In one embodiment, the implanted substrate is thermally annealed with an electron beam. In this embodiment, the implanted substrate is heated with an electron beam to a peak temperature, held at the peak temperature for a predetermined time and the substrate temperature is then decreased.

Preferably, the donor ions are selected from hydrogen, lithium, aluminium and gallium ions. More preferably, the donor ions are hydrogen ions.

Preferably, the step of implanting donor ions uses a mass-separated focussed beam of low energy donor ions.

Preferably, the donor ions are implanted with a beam energy below about 70 keV. In certain embodiments, the donor ions are implanted with a beam energy between about 5 keV and about 70 keV. Alternatively, the donor ions may be implanted with a beam energy between about 5 keV and about 50 keV. In other preferred embodiments, the donor ions are implanted with a beam energy below about 45 keV, below about 40 keV, below about 35 keV, below about 30 keV, or below about 25 keV.

In those embodiments wherein the donor ion is hydrogen, the donor ions are preferably implanted with energies below about 50 keV. In other preferred embodiments, wherein the donor ion is hydrogen, the donor ions are implanted with a beam energy below about 45 keV, below about 40 keV, below about 35 keV, below about 30 keV, or below about 25 keV. In certain embodiments, wherein the donor ion is hydrogen, the donor ions are implanted with a beam energy above about 5 keV.

Preferably, the resultant atomic % of donor in the substrate is below about 10 atomic %. More preferably, the atomic % of donor in the substrate is between about 0.01 atomic % and about 5.0 atomic %.

In a further aspect, the present invention provides p-type ZnO prepared substantially according to the method of the invention.

In another aspect, the present invention provides a method of preparing a p-n junction or an n-p-n/p-n-p junction wherein the p-type material is p-type ZnO prepared substantially according to the method of the invention.

In another aspect, the present invention provides a p-n junction or an n-p-n/p-n-p junction prepared substantially according to the method of the invention.

The present invention also contemplates devices comprising the p-type ZnO or a p-n junction or an n-p-n/p-n-p junction of the invention.

In another aspect, the present invention provides a method of preparing p-type ZnO substantially as herein described and with reference to any one or more of the accompanying drawings and/or examples.

In another aspect, the present invention provides p-type ZnO substantially as herein described and with reference to any one or more the accompanying drawings and/or examples.

In another aspect, the present invention provides a method of preparing a p-n junction or an n-p-n/p-n-p junction substantially as herein described and with reference to any one or more the accompanying drawings and/or examples.

In another aspect, the present invention provides a p-n junction or an n-p-n/p-n-p junction substantially as herein described and with reference to any one or more the accompanying drawings and/or examples.

Other aspects of the invention may become apparent from the following description which is given by way of example only and with reference to the accompanying drawings.

As used herein the term “and/or” means “and” or “or”, or both.

As used herein “(s)” following a noun means the plural and/or singular forms of the noun.

The term “comprising” as used in this specification means “consisting at least in part of”. When interpreting each statement in this specification that includes the term “comprising”, features other than that or those prefaced by the term may also be present. Related terms such as “comprise” and “comprises” are to be interpreted in the same manner.

As used herein the term “donor ion” means an ion introduced to semiconductor to generate a free electron (by “donating” an electron to the semiconductor).

As used herein the term “acceptor ion” means an ion introduced to semiconductor to generate a free hole (by “accepting” an electron from the semiconductor and “releasing” a hole at the same time).

As used herein the terms “low energy acceptor ion” and “low energy donor ion” mean an ion beam energy range from about 1 to about 100 keV.

This invention may also be said broadly to consist in the parts, elements and features referred to or indicated in the specification of the application, individually or collectively, and any or all combinations of any two or more of said parts, elements or features, and where specific integers are mentioned herein which have known equivalents in the art to which this invention relates, such known equivalents are deemed to be incorporated herein as if individually set forth.

### BRIEF DESCRIPTION OF DRAWINGS

The invention will now be described by way of example only and with reference to the drawings in which:

FIG. 1: is a plot of the carrier concentration for an as-deposited ZnO thin film on a silicon substrate and for ZnO thin films, which have been implanted with different fluences of nitrogen acceptor ions or with different fluences of hydrogen donor ions and nitrogen acceptor ions and annealed, on a silicon substrate;

FIG. 2: is a plot of the carrier mobility for an as-deposited ZnO thin film on a silicon substrate and for ZnO thin films, which have been implanted with different fluences of nitrogen acceptor ions or with different fluences of hydrogen donor ions and nitrogen acceptor ions and annealed, on a silicon substrate;

FIG. 3: is a plot of the photoluminescence for ZnO thin films, which have been implanted with nitrogen acceptor ions or with hydrogen donor ions and nitrogen acceptor ions and annealed, on a silicon substrate;

FIG. 4: is a plot of the photoluminescence for a ZnO thin film, which has been implanted with nitrogen acceptor ions and annealed, on a SiO₂ substrate;

FIG. 5: is a plot of the photoluminescence for a bulk ZnO single crystal which has been implanted with nitrogen acceptor ions and annealed; and

FIG. 6: is a plot of the I-V characteristics for a bulk ZnO single crystal which has been implanted with nitrogen acceptor ions and annealed.

### DETAILED DESCRIPTION OF INVENTION

The method of the present invention involves the formation of p-type ZnO using doping by low energy ion implantation followed by electron beam annealing. Utilising the method exemplified herein, up to 100 nm thick p-type ZnO surface layers can be formed on n-type ZnO materials.

### N-type ZnO Substrate

The methods exemplified herein have been applied to bulk n-type ZnO substrates and to films of ZnO on a second bulk material (such as silicon and SiO₂). A relatively low energy ion implantation is preferably used, so that implantation and modification of the n-type ZnO substrate occurs on the nanometre scale, preferably to a depth of below about 100 nm.

The method of the invention utilises an n-type ZnO substrate. This can be produced as a thin film or a bulk crystal by conventional techniques including, but not limited to: sputtering; MBE; MOCVD; and hydrothermal growth. Suitable substrates are known and are also commercially available. It will be appreciated by those persons skilled in the art that the n-type ZnO substrate can be undoped, or that at least the surface layers of the n-type ZnO substrate can be modified by known doping techniques.

### Ion Implantation

Ion implantation is a process by which ions of an element can be implanted into another solid, thereby changing the chemical and/or physical properties of the solid. Ion implantation is especially useful where it is desired to introduce a chemical or structural change near the surface of a target. The ions introduce both a chemical change in the target, because they can be a different element than the target, and a structural change, because the crystal structure of the target can be damaged or even destroyed.

Ion implantation equipment typically comprises: an ion source; an accelerator, where the ions are electrostatically accelerated to a high energy; beam guidance systems; and a target chamber, where the ions impinge on a target, which is the substrate to be implanted.

Typical ion energies for ion implantation are in the range of 10-500 keV. In the methods of the present invention, it is preferred that the ions only penetrate the substrate to a depth of between about 1 nm and about 100 nm, so the ion energies are relatively low—between about 1 keV and about 100 keV. Ion energies lower than this range result in very little damage to the target or penetration into the substrate, and fall under the designation ion beam deposition rather than ion implantation.

Those persons skilled in the art will appreciate that there is a relationship between the depth to which an ion will penetrate the n-type ZnO substrate and both the nature and energy of that ion. For example, we have observed that 23 keV nitrogen ions will penetrate n-type ZnO to a depth of about 80 nm, while hydrogen ions with the same energy will penetrate n-type ZnO to a depth of about 300 nm.

In those embodiments wherein the acceptor ion is nitrogen, the acceptor ions are preferably implanted with a beam energy below about 70 keV, more preferably below about 50 keV. In other preferred embodiments, wherein the acceptor ion is nitrogen, the acceptor ions are implanted with a beam energy below about 45 keV, below about 40 keV, below about 35 keV, below about 30 keV, or below about 25 keV. In certain embodiments, wherein the acceptor ion is nitrogen, the acceptor ions are implanted with a beam energy above about 5 keV.

In those embodiments wherein the donor ion is hydrogen, the donor ions are preferably implanted with energies below about 50 keV. In other preferred embodiments, wherein the donor ion is hydrogen, the donor ions are implanted with a beam energy below about 45 keV, below about 40 keV, below about 35 keV, below about 30 keV, or below about 25 keV. In certain embodiments, wherein the donor ion is hydrogen, the donor ions are implanted with a beam energy above about 5 keV.

The ion fluence is the product of the ion flux that is incident on the substrate during implantation and time. In a preferred embodiment of the present invention, the ion fluence is between about 1.0×10¹⁵ ions/cm² and about 5.0×10¹⁶ ions/cm².

### Electron Beam Annealing

Rapid thermal electron beam annealing (EBA) is used in the heating/annealing step following implantation of the acceptor ions. EBA is a very precise technique whereby the target can be heated in a controlled fashion under a high vacuum—a residual gas pressure of less than about 1×10⁻⁶ mbar. In a preferred embodiment, the residual gas pressure is less than about 1×10⁻⁷ mbar.

In a preferred embodiment of the method of the invention, the EBA apparatus includes a liquid nitrogen trap positioned close to the sample holder in order to maintain a sufficiently impurity-free (for example, hydrocarbon-free) environment throughout the annealing step. It is important to use a sufficiently impurity-free environment during the EBA because the ZnO substrate target is penetrated and damaged during the ion implantation step, making it susceptible to any impurity.

In the electron beam annealing step, the target is heated to a peak temperature of about 500° C. to about 1,200° C., held at the peak temperature and then cooled down to room temperature. In a preferred embodiment, the peak temperature is between about 500° C. and about 1,000° C.

The scope of the present invention encompasses two particularly preferred methods for doping the substrate by implanting low energy ions, prior to the electron beam annealing. These methods are non-limiting.

### 1. Single Ion (Acceptor) Doping

This method involves:
doping the ZnO substrate with low-energy acceptor ions; then
electron beam annealing.

More specifically, this method utilises low energy acceptor ion implantation with various fluences (generally between about 1×10¹⁵ and about 5×10¹⁶ ions cm⁻²), which correspond to up to 10 atomic percent into the n-type ZnO substrate. Suitable low energy acceptor ions include, but are not limited to nitrogen, phosphorus and arsenic ions. After ion implantation the samples are heated to a peak temperature of between about 500° C. and about 1,200° C. under high vacuum conditions, held at this temperature for few minutes and then cooled.

We have found that all of the implanted and electron beam annealed ZnO samples show p-type characteristics, with various carrier concentrations and mobilities. However, the ZnO substrate remains n-type ZnO in the absence of an annealing step after low energy acceptor ion implantation.

### 2. Co-Ion (Donor and Acceptor) Doping

This co-doping method involves an initial process of:
doping the ZnO substrate with low-energy donor ions; and then optionally;
thermal annealing;
   followed by the same steps as the single ion (acceptor) doping method i.e.:
doping the ZnO substrate with low-energy acceptor ions; then
electron beam annealing.

The co-ion (donor and acceptor) doping method includes the pre-step/s of low energy donor ion implantation with or without thermal annealing. Suitable low energy donor ions include, but are not limited to hydrogen, lithium, aluminium and gallium ions. This method alters the n-type conductivity of the ZnO substrate first, then the targets are implanted with low energy acceptor ions—as in the single ion (acceptor) doping method—and electron beam annealed with a peak temperature of between about 500° C. and about 1,200° C., which is held for few minutes.

We found that all of the donor ion implanted and annealed ZnO samples show changes in n-type conductivity. These changes can be either an increase or a decrease in conductivity depending upon the conditions of the implantation, for example, the choice of donor ion etc. The p-type ZnO prepared using the co-ion (donor and acceptor) doping method samples shows p-type characteristics with particular carrier concentrations and mobilities. The co-ion doping method results in a significant increase in observed mobilities compared to carrier concentrations.

Utilising the methods of the present invention a layer up to 100 nm thick of an n-type ZnO substrate can be modified to p-type. The methods of the present invention provide p-type ZnO with high p-type carrier mobility. The carrier mobility observed in reported p-type ZnO is in the range 0.5-5 cm²·Vs⁻¹. Utilising the methods of the present invention, p-type ZnO having mobilities in the range 1-500 cm²·Vs⁻¹ can be prepared.

The methods of the present invention provide p-type ZnO with very high carrier concentrations. The carrier concentration observed in reported p-type ZnO is in the range 1.0×10¹³-5.0×10¹⁷ cm⁻³. Utilising the methods of the present invention, p-type ZnO having carrier concentrations in the range 1.0×10¹³-5.0×10¹⁹ cm⁻³ can be prepared.

Advantageously, the methods of the present invention enable easy control over dopant concentration and over dopant depth—depth of implantation—to within about 1% accuracy.

### Electrical Properties

The p-type ZnO prepared using the single ion (acceptor) doping method followed by EBA typically has a p-type carrier concentration almost twice that of p-type ZnO prepared using co-ion (donor and acceptor) doping method without the intermediate, post-donor implantation annealing step, and with EBA carried out only after acceptor implantation. In contrast, the carrier mobility is higher in the p-type ZnO prepared using the latter method compared to that prepared using the single ion (acceptor) doping method. Without wishing to be bound by theory, it is believed that this observed difference may be due to the ion beam damage effect. The properties of the p-type ZnO prepared using co-ion (donor and acceptor) doping method with two annealing steps (after donor implantation and after acceptor implantation) are similar to those of the p-type ZnO prepared using the single ion (acceptor) doping method followed by EBA.

### Optical Properties

We have observed UV near band edge emission peaks from 365-400 nm for p-type ZnO prepared using both of the methods described above. The spectra include a peak at 374 nm (3.317 eV) which is a clear indication of an acceptor-bound exciton that is associated with Nₒ acceptor. In addition, the donor-acceptor pair (DAP) emission peak, which involves the Nₒ acceptor, was measured at 382 nm (3.24 eV). The peak intensity of the DAP peak is relatively high for the p-type ZnO prepared using co-ion (donor and acceptor) doping method compared to that for the p-type ZnO prepared using the single ion (acceptor) doping method. This means that the doped hydrogen donor along with nitrogen acceptor has relatively high emission.

As discussed above we have developed two particularly preferred embodiments of the method of the invention. These non-limiting embodiments of the invention are discussed in detail below.

### 1. Single Ion (Acceptor) Doping

The steps used in a first non-limiting embodiment of the method of the present invention are:
1) Target preparation
2) Load target into high vacuum implantation chamber
3) Low energy acceptor ion implantation into target
4) Transfer the implanted target into high vacuum electron beam annealing facility
5) Anneal target with electron beam
   N-type zinc oxide crystals and thin films grown with various techniques can be used as the target substrate in step 1. The targets are typically cut into 0.4×0.4 cm or 1×1 cm sizes and mechanically cleaned by spraying pressured air on to surface of the n-type ZnO.

In step 2, the target is mounted on an implantation target holder that is kept at room temperature. The implantation holder is inserted into the implantation chamber. Implantation is typically started when the residual gas pressure is about 10⁻⁷ mbar.

In step 3, a mass-separated focussed ion beam of low energy acceptor ions is raster scanned over the surface of the target to allow for a homogeneous implantation. Once the required ion fluence is reached—typically between about 1.0×10¹⁵ ions/cm² and about 5.0×10¹⁶ ions/cm² or about 0.1 to about 10 atomic percent of the n-type ZnO substrate—the implantation ion beam is shut off.

After the implantation, the targets are transferred from the implantation chamber to the electron beam annealing chamber in step 4. Transfer time is not important. The implanted samples can be stored under environmentally controlled conditions—i.e. in a clean environment, at low humidity and at a typical room temperature of about 20° C.—for days.

In step 5, the targets are annealed with an electron beam. Typically, annealing begins once the residual gas pressure is lowered to about 1×10⁻⁶ mbar. The target is heated to a peak temperature of between about 500° C. and about 1,200° C., held at this temperature for few minutes and then cooled to room temperature.

After annealing, the targets may be removed from the annealing chamber into the ambient atmosphere.

Various techniques known to those persons skilled in the art can be used for the electrical and optical characterisation of the resultant p-type ZnO. For example, the electrical properties can be determined using Hall probe techniques.

Typically, Hall probe techniques utilise ohmic contacts about 10 to about 100 nm thick that are placed on the four corners of the acceptor implanted and annealed targets. The targets are mounted onto a circuit board attached to a Hall probe system. The p-type ZnO prepared using the single ion (acceptor) doping method followed by EBA showed p-type carrier concentration values from 1.0×10¹³-5.0×10¹⁹ cm⁻³, hole mobilities of 1-500 cm²·Vs⁻¹ and resistivities of 0.0001-10 ohm·cm.

The optical properties of the p-type ZnO can be determined, for example, using photoluminescence techniques.

Photoluminescence (PL) spectra are often used to characterise semiconductor materials. Such spectra can provide information about the energy level of the impurity in the band gap. The PL spectrum is usually composed of two components. One is located in the UV range due to excitonic-related emission and the other is in the visible emission band.

The optical properties of a semiconductor are connected with both intrinsic and extrinsic defects. Intrinsic optical transitions take place between the electrons in the conduction band and holes in the valence band, including excitonic effects due to Coulomb interaction. PL is a powerful technique for studying exciton structure.

Typically, the acceptor implanted and annealed targets are mounted on standard PL apparatus. PL measurements are typically performed at different temperatures. The targets showed a broad peak in the wavelength region between 500-850 nm and exciton peaks in the region between 300-450 nm were observed. These exciton peaks correspond to p-type ZnO formed as a result of the acceptor doping process of low energy acceptor ion implantation and EB annealing.

### 2. Co-Ion (Donor and Acceptor) Doping

The steps used in a second non-limiting embodiment of the method of the present invention are:
1) Target preparation
2) Load target into high vacuum implantation chamber
3) Low energy donor ion implantation into target
4) Optionally, load target into thermal annealing facility and thermally anneal target
5) Load target into high vacuum implantation chamber
6) Low energy donor ion implantation into target
7) Transfer the implanted target into high vacuum electron beam annealing facility
8) Anneal target with electron beam
   N-type zinc oxide crystals and thin films grown with various techniques can be used as the target substrate in step 1. The targets are typically cut into 0.4×0.4 cm or 1×1 cm sizes and mechanically cleaned by spraying pressured air on to surface of the n-type ZnO.

In step 2, the target is mounted on an implantation target holder that is kept at room temperature. The implantation holder is inserted into the implantation chamber. Implantation is typically started when the residual gas pressure is about 10⁻⁷ mbar.

In step 3, a mass-separated focussed ion beam of low energy donor ions is raster scanned over the surface of the target to allow for a homogeneous implantation. Once the required ion fluence is reached—typically corresponding to about 0.01 to about 10 atomic percent of the n-type ZnO substrate—the implantation ion beam is shut off.

After the implantation, the targets are optionally transferred from the implantation chamber to a annealing facility in step 4. Transfer time is not important. The implanted samples can be stored under environmentally controlled conditions—i.e. in a clean environment, at low humidity and at a typical room temperature of about 20° C.—for days.

The targets are then optionally thermally annealed at less than atmospheric pressure. This involves heating the target, holding the target at a peak temperature for a time, and then cooled.

Suitable methods for heating the substrate are known to those persons skilled in the art. These include, but are not limited to, the use of: electron beams; furnaces; and other methods of delivering thermal energy to the substrate.

Advantageously, electron beam annealing enables precise control over both the temperature gradient and peak temperature. However, the method of the invention is not limited to the use of electron beam annealing. For example, a furnace may be used to thermally anneal the target.

A person skilled in the art will be able to select appropriate conditions for the thermal annealing process without undue experimentation. The conditions, including the rate of heating, the peak temperature and the rate of cooling, will depend on the annealing method, the ZnO substrate and the ion fluence.

The thermal annealing process typically begins at room temperature and proceeds in three stages. In the first stage the sample is heated to the peak temperature. In the second stage the peak temperature is maintained for a period of time. In the third stage of the annealing process the substrate is allowed to cool to room temperature before removing from the annealing apparatus.

The peak temperature is typically about 500-1200° C. This temperature will depend inter alia on the annealing method. For example, while annealing with an electron beam may be able to provide a maximum temperature of about 1200° C., a furnace may be unable to maintain a maximum temperature of more than about 1000° C.

The time for which the maximum temperature is maintained is typically about 5 seconds to about 2 hours, however longer times could be used. This time will also depend on the annealing method. Extended annealing times may not provide any further benefit.

In one embodiment, the targets may be annealed with an electron beam. In this embodiment annealing typically begins once the residual gas pressure is lowered to about 1×10⁻⁶ mbar. The target is heated to a peak temperature of between about 500° C. and about 1,200° C., held at this temperature for few minutes and then cooled to room temperature.

After annealing, the targets may be removed from the annealing chamber into the ambient atmosphere.

If required, various techniques, such as those described above, can be used for the electrical and optical characterisation of the donor-implanted targets.

After the optional thermal annealing, the target is mounted on an implantation target holder that is kept at room temperature in step 5. The implantation holder is inserted into the implantation chamber. Implantation is typically started when the residual gas pressure is about 10⁻⁷ mbar.

In step 6, a mass-separated focussed ion beam of low energy acceptor ions is raster scanned over the surface of the target to allow for a homogeneous implantation. Once the required ion fluence is reached—typically between about 1.0×10¹⁵ ions/cm² and about 5.0×10¹⁶ ions/cm² or about 0.1 to about 10 atomic percent of the n-type ZnO substrate—the implantation ion beam is shut off.

After the implantation, the targets are transferred from the implantation chamber to the electron beam annealing chamber in step 7. Transfer time is not important. The implanted samples can be stored under environmentally controlled conditions—i.e. in a clean environment, at low humidity and at a typical room temperature of about 20° C.—for days.

In step 8, the targets are annealed with an electron beam. Typically, annealing begins once the residual gas pressure is lowered to about 1×10⁻⁶ mbar. The target is heated to a peak temperature of between about 500° C. and about 1,200° C., held at this temperature for few minutes and then cooled to room temperature.

After annealing, the targets may be removed from the annealing chamber into the ambient atmosphere.

Various techniques known to those persons skilled in the art can be used for the electrical and optical characterisation of the resultant p-type ZnO. For example, the electrical properties can be determined using Hall probe techniques and the optical properties using photoluminescence techniques, such as those described above for the single ion (acceptor) doping method.

### EXAMPLES

### Example 1

### ZnO Film on Si Substrate

### Single Ion Doping Protocol

We took a 1×1 cm Si(100) substrate, mechanically cleaned it by spraying pressured air on to the surface and deposited a n-type ZnO thin film of around 300 nm. The targets were loaded into a high vacuum implantation chamber. 23 keV nitrogen ions (the acceptor) were implanted in an area of around 1 cm² with various fluences starting from 1×10¹⁵ ions/cm² to 5×10¹⁶ ions/cm². The implantation depth was around 80 nm. The sample coded A corresponds to an implantation fluence of 1×10¹⁵ ions/cm², which equates to around 0.2 atomic percent of N. The sample coded B corresponds to 2×10¹⁵ ions/cm², which equates to around 0.4 atomic percent of N. The sample C corresponds to 2.5×10¹⁶ ions/cm², which equates to around 5 atomic percent of N. The sample D corresponds to 5×10¹⁶ ions/cm², which equates to around 10 atomic percent of N. After the implantation, the targets were annealed with a raster scanned electron beam at 800° C. for 15 minutes with a temperature gradient of 5° C./s.

### Co-Ion Doping Protocol:

We took a 1×1 cm Si(100) substrate, mechanically cleaned it by spraying pressured air on to the surface and deposited a n-type ZnO thin film of around 300 nm. The targets were loaded into a high vacuum implantation chamber. First 23 keV hydrogen ions (the donor) were implanted in an area of around 1 cm² then nitrogen ions (the acceptor) were implanted in an area of around 1 cm² with various fluences starting from 1×10¹⁵ ions/cm² to 5×10¹⁶ ions/cm². The implantation depth for hydrogen ion was around 300 nm. The sample coded A corresponds to an implantation fluence of 1×10¹⁵ ions/cm² which equates to around 0.1 atomic percent of H. The sample coded B corresponds to 2×10¹⁵ ions/cm² which equates to around 0.2 atomic percent of H. The sample coded C corresponds to 2.5×10¹⁶ ions/cm² which equates to around 2.5 atomic percent of H.

Following the hydrogen implantation, 23 keV nitrogen ions were implanted with the same fluences described above.

After the hydrogen and nitrogen implantation, the targets were annealed with a raster scanned electron beam at 800° C. for 15 minutes with a temperature gradients of 5° C./s.

Titanium, titanium/gold and nickel/gold ohmic contacts around 10-100 nm thick were made on the four corner of the implanted and annealed targets along with an as-deposited n-type ZnO film. The targets were mounted on a circuit board attached to a Hall probe system to determine the electrical properties.

The electrical properties of the as-deposited (undoped) ZnO film on silicon showed n-type carrier concentration values of −1.0×10¹⁶-5.0×10¹⁸ cm⁻³, hole mobilities of 1-5 cm²·Vs⁻¹ and resistivities of 0.01-0.1 ohm·cm.

The electrical properties of ZnO films deposited on silicon (Samples coded A, B, C and D), after implanting of the acceptor ion (nitrogen) and annealing, showed p-type carrier concentration values of 2×10¹⁸ to 4.0×10¹⁸ cm⁻³, hole mobilities of 1-300 cm²·Vs⁻¹ and resistivities of 0.001-1 ohm·cm.

The electrical properties of co-ion implanted and annealed (donor ion—hydrogen and acceptor ion—nitrogen) ZnO films deposited on silicon showed p-type carrier concentration values of 1×10¹⁸ to 3.0×10¹⁸ cm⁻³, hole mobilities of 1-400 cm²·Vs⁻¹ and resistivities of 0.001-0.01 ohm·cm.

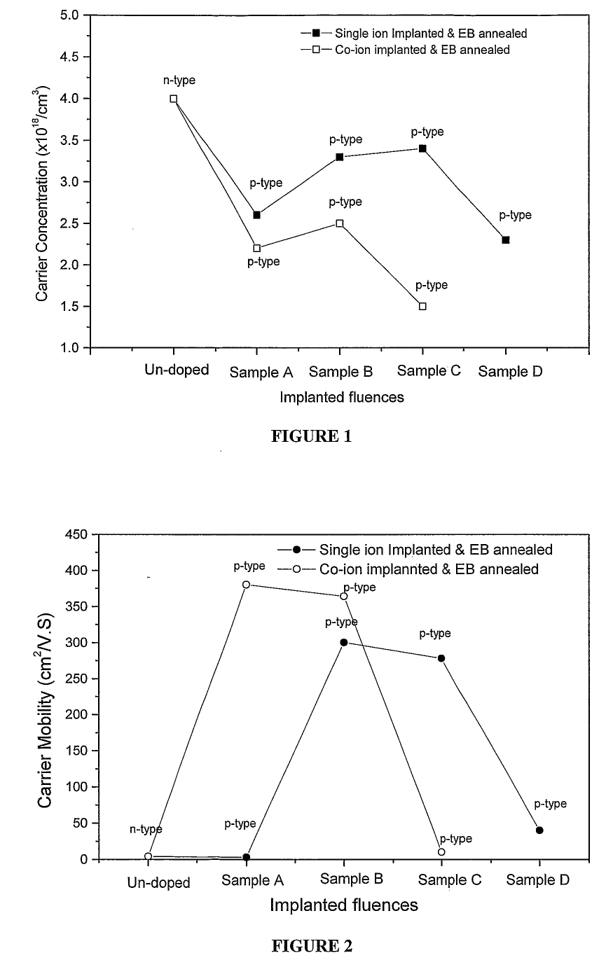

FIG. 1 shows the carrier concentration plot for the undoped target and the targets implanted with different fluences. The carrier concentration started to change to p-type (Sample A) from the undoped sample. For the low fluence implanted target (A) there was a lower carrier concentration whilst the medium fluence implanted targets (B, C) provided a higher carrier concentration and the high fluence implanted target (D) resulted in a low carrier concentration.

FIG. 2 shows the carrier mobility plot for the undoped target and the implanted and annealed targets. For the single ion implanted targets, the carrier mobility remained of the same order of magnitude for the lower fluence implanted target (A), increased by an order of magnitude for the samples B and C, and then started to decrease for the sample D.

For the co-ion implanted targets, high carrier mobility was measured on samples A and B.

### Photoluminescence (PL) Spectra

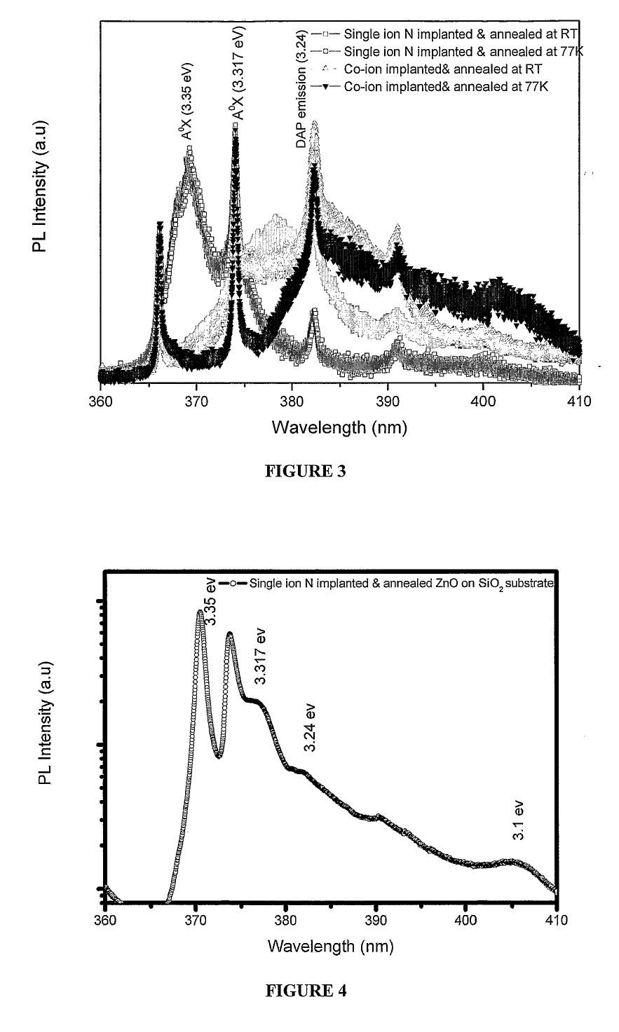

The optical properties of the targets were investigated by PL. The results for Sample B are shown in FIG. 3. PL measurements were performed at different temperatures (for example, room temperature and 77K). The exciton peaks, which correspond to p-type ZnO formed as a result of the doping of acceptors by low-energy ion implantation and EB annealing, are observed between 360-450 nm. The most prominent lines at 3.24 eV and 3.32 eV are observed in the p-type ZnO samples. In addition to those lines, another acceptor bound exciton peak is observed at 3.35 eV.

### Example 2

### ZnO film on SiO₂ Substrate

We took a 1×1 cm 500 nm thick silicon dioxide (SiO₂, 100) on Si substrate, mechanically cleaned it by spraying pressured air on to the surface and deposited a n-type ZnO thin film of around 300 nm. The targets were loaded into a high vacuum implantation chamber. 23 keV nitrogen ions (the acceptor) were implanted in an area of around 1 cm² with various fluences starting from 1×10¹⁵ ions/cm² to 5×10¹⁶ ions/cm². The implantation depth was around 80 nm. After the implantation, the targets were annealed with a raster scanned electron beam at 800° C. for 15 minutes with a temperature gradient of 5° C./s.

The electrical properties of ZnO films deposited on SiO₂, after implanting of the acceptor ion (nitrogen) and annealing, showed p-type carrier concentration values of 2×10¹⁷ to 4.0×10¹⁸ cm⁻³, hole mobilities of 1-100 cm²·Vs⁻¹ and resistivities of 0.1-10 ohm·cm.

### Photoluminescence (PL) Spectra

The optical properties of the ZnO films deposited on SiO₂, after implanting of the acceptor ion (nitrogen) and annealing, were investigated by PL. The results for the sample implanted with a fluence of 2×10¹⁵ ions/cm² are shown in FIG. 4. These PL measurements were performed at 77K. The exciton peaks, which correspond to p-type ZnO formed as a result of the doping of acceptors by low-energy ion implantation and EB annealing, are observed between 360-450 nm. The most prominent lines in the spectrum are at 3.31 eV and 3.24 eV. Another acceptor bound exciton peak is observed at 3.35 eV. A further, broad peak is also observed around 405 nm (3.1 eV).

### Example 3

### Bulk ZnO

We took a 1×1 cm bulk n-type ZnO single crystal obtained from a commercial supplier. The targets were loaded into a high vacuum implantation chamber. 23 keV nitrogen ions (the acceptor) were implanted in an area of around 1 cm² with various fluences starting from 1×10¹⁵ ions/cm² to 5×10¹⁶ ions/cm². The implantation depth was around 80 nm. After the implantation, the targets were annealed with the raster scanned electron beam at 800° C. for 15 minutes with a temperature gradient of 5° C./s.

The electrical properties of the ZnO single crystal, after implantation of the acceptor ion (nitrogen) and annealing, showed p-type carrier concentration values of 1×10¹³ to 1.0×10¹⁸ cm⁻³, hole mobilities of 1-300 cm²·Vs⁻¹ and resistivities of 0.01-100 ohm·cm. These properties are estimated from the properties determined for the ZnO thin films. Those persons skilled in the art will appreciate that some of the techniques used to characterise the thin films are not suitable for characterising the bulk single crystal ZnO.

### Photoluminescence (PL) Spectra

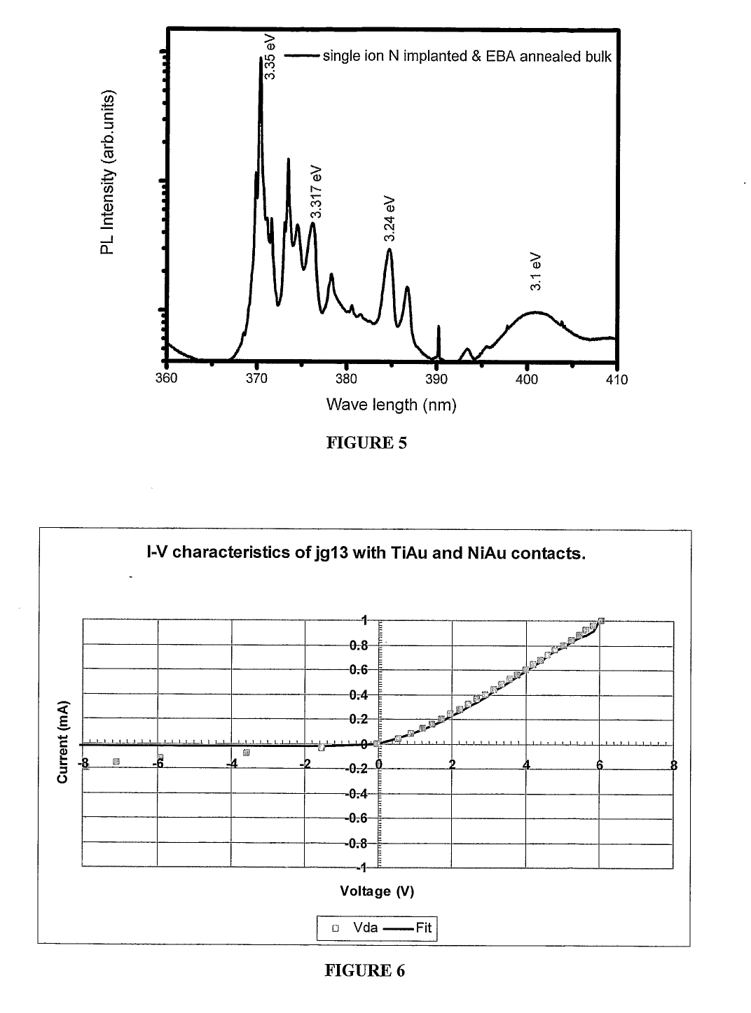

The optical properties of the bulk ZnO single crystals, after implanting of the acceptor ion (nitrogen) and annealing, were investigated by PL. The results for the single crystal implanted with a fluence of 2×10¹⁵ ions/cm² are shown in FIG. 5. These PL measurements were performed at 77K. The exciton peaks, which correspond to p-type ZnO formed as a result of the doping of acceptors by low-energy ion implantation and EB annealing, are observed between 360-450 nm. The most prominent lines in the spectrum are at 3.31 eV and 3.24 eV. Another acceptor bound exciton peak is observed at 3.35 eV. A further, broad peak is also observed around 405 nm (3.1 eV) due to the nitrogen acceptor doping into the bulk ZnO target.

### I-V Characteristics

The I-V characteristics of the bulk ZnO single crystals, after implanting of the acceptor ion (nitrogen) and annealing, were investigated. A thin layer of titanium/gold was used for n-type contact and nickel/gold was used to make a contact on the p-type ZnO. FIG. 6 shows the I-V characteristics of a bulk ZnO substrate, after implanting with a fluence of 2×10¹⁵ ions/cm² and annealing, at 300 K. The observed I-V characteristics originate within the ZnO p-n junction that is formed from the p-type ZnO prepared as described above and the bulk n-type ZnO substrate.

Where in the foregoing description reference has been made to elements or integers having known equivalents, then such equivalents are included as if they were individually set forth.

In addition, where features or aspects of the invention are described in terms of Markush groups, those skilled in the art will recognise that the invention is also thereby described in terms of any individual member or subgroup of members of the Markush group.

### INDUSTRIAL APPLICABILITY

The present invention provides a method of preparing p-type zinc oxide (ZnO). The p-type ZnO that can be prepared using a method of the invention may be used to prepared a p-n junction or an n-p-n/p-n-p junction.

The p-type ZnO may have application in various optoelectronic devices, particularly short wavelength devices. Such devices include light emitting diodes (LEDs), particularly ultraviolet/blue LEDs, and lasers. White light LEDs may be prepared using p-type ZnO with other dopants, such as magnesium and cadmium. In addition, the p-type ZnO may have application in the fabrication of information storage devices, field effect transistors, piezoelectric devices, and gas, chemical and biological sensing devices.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

### REFERENCES

Bagnall, D. M., Y. F. Chen, Z. Zhu, T. Yao, S. Koyama, M. Y. Shen and T. Goto, Appl. Phys. Lett. 70 (1997) 2230.
Dutta, A. and S. Basu, Mater. Chem. Phys. 34 (1993) 41.
Guo, X.-L., H. Tabata and T. Kawai, J. Crystal Growth 223 (2001)135.
Garces, N. Y., L. Wang, N. C. Giles, L. E. Halliburton, G. Cantwell and D. B. Eason, J. Appl. Phys. 94 (2003) 519.
Joseph, M., H. Tabata and T. Kawai, Jpn. J. Appl. Phys 38 (1999) L1205.
Kaschner, A., U. Haboeck, M. Strassburg, M. Strassburg, G. Kaczmarczyk, A. Hoffmann and C. Thomsen, Appl. Phys. Lett. 80 (2002)1909.
Look, C. D., Mater. Sci. Eng. B 80 (2001) 383.
Minegishi, K., Y. Koiwai, Y. Kikuchi, K. Yano, M. Kasuga, A. Shimizu, Jpn. J. Appl. Phys 36 (1997) L1453.
Miyakawa, M., K. Ueda and H. Hosono, Nucl. Instr. and Meth. B 191 (2002)173.
Pearton, S. J., C. B. Vartuli, J. C. Zolper, C. Yuan and R. A. Stall, Appl. Phys. Lett. 67 (1995) 1435.
Ryu, Y. R., S. Zhu, D. C. Look, J. M. Wrobel, H. M. Jeong and H. W. White, J. Cryst. Growth 216 (2000) 330.
Thomas, B. W. and D. Walsh, J. Phys. D: Appl. Phys. 6 (1973) 612.
Vaithianathan, V., B.-T. Lee and S. S. Kim, J. Appl. Phys. 98 (2005) 043519.
Wenas, W. W., A. Yamada, M. Konagai and K. Takahashi, Jpn. J. Appl. Phys 33 (1994) L283.
Yamamoto, T. and H. Katayama-Yoshida, Jpn. J. Appl. Phys 38 (1999) L166.
Yan, Y., S. B. Zhang and S. T. Pantelides, Phys. Rev. Lett. 86 (2001) 5723.
Zolper, J. C., R. G. Wilson, S. J. Pearton and R. A. Stall, Appl. Phys. Lett. 68 (1996) 1945.

1. A method of preparing p-type zinc oxide (ZnO) comprising the steps of:
providing an n-type ZnO substrate;
doping the substrate by implanting low energy acceptor ions into the substrate; and
in a chamber at less than atmospheric pressure, heating the implanted substrate with an electron beam to a peak temperature, holding the peak temperature for a predetermined time and decreasing the substrate temperature.

2-4. (canceled)

5. A method as claimed in claim 1, wherein the acceptor ions are selected from nitrogen, arsenic, and phosphorus ions.

6. A method as claimed in claim 1, wherein the acceptor ions are nitrogen ions.

7. A method as claimed in claim 1, wherein the step of implanting low energy acceptor ions uses a focussed beam of mass-separated low energy acceptor ions having a beam energy below about 70 keV.

8. A method as claimed in claim 7, wherein the ion fluence during the implanting is between about 1×10 ions cm⁻² and about 5×10 ions cm².

9. (canceled)

10. A method as claimed in claim 7, wherein the acceptor ions are implanted with a beam energy between about 5 keV and about 70 keV.

11. A method as claimed in claim 7, wherein the acceptor ions are implanted with a beam energy below about 45 keV, 40 keV, 35 keV, 30 keV, or 25 keV.

12-15. (canceled)

16. A method as claimed in claim 1, wherein the resultant atomic % of acceptor in the substrate is below about 10 atomic %.

17. A method as claimed in claim 1, wherein the resultant atomic % of acceptor in the substrate is between about 0.1 atomic % and about 5.0 atomic %.

18-27. (canceled)

28. A method as claimed in claim 1 further comprising, prior to the step of implanting low energy acceptor ions into the substrate, the additional step(s) of:
pre-doping the substrate by implanting donor ions into the substrate; and, optionally,
in a chamber at less than atmospheric pressure, thermally annealing the implanted substrate.

29. (canceled)

30. A method as claimed in claim 10, wherein the donor ions are selected from hydrogen, lithium, aluminium and gallium ions.

31. A method as claimed in claim 10, wherein the donor ions are hydrogen ions.

32. A method as claimed in claim 10, wherein the donor ions are implanted using a focussed beam of mass-separated low energy donor ions having a beam energy below about 50 keV.

33. (canceled)

34. A method as claimed in claim 32, wherein the donor ions are implanted with a beam energy between about 5 keV and about 50 keV.

35. A method as claimed in claim 32, wherein the donor ions are implanted with a beam energy below about 45 keV, 40 keV, 30 keV, 30 keV, or 25 keV.

36-39. (canceled)

40. A method as claimed in claim 10, wherein the resultant atomic % of donor in the substrate is below about 10 atomic %.

41. A method as claimed in claim 10, wherein the atomic % of donor in the substrate is between about 0.01 atomic % and about 5.0 atomic %.

42-43. (canceled)

44. A method as claimed in claim 1, wherein the p-type carrier mobility of the resultant p-type ZnO is 1-500 cm²‘Vs⁻¹.

45. A method as claimed in claim 1, wherein the carrier concentration of the resultant p-type ZnO is in the range 1.0×10¹³-5.0×10¹⁹ cm⁻³.

46. A method as claimed in claim 1, wherein the resistivity of the resultant p-type ZnO is between 0.0001-10 ohm·cm.

47-49. (canceled)
